(19) United States
(12) Patent Application Publication
(10) Pub. No.: US 2009/0321724 A1
(43) Pub. Date: Dec. 31, 2009

(54) Material for Producing a Functional Layer of an Organic Electronic Component

(76) Inventors: Walter Fix, Nurnberg (DE); Jasmin Worle, Furth (DE)

Correspondence Address: CARELLA, BYRNE, BAIN, GILFILLAN, CECCHI,;STEWART & OLSTEIN, 5 BECKER FARM ROAD, ROSELAND, NJ, 07068, US

(21) Appl. No.: 12/375,251

(22) PCT Filed: Jul. 27, 2007
(86) PCT No.: PCT/EP07/06675

§ 371 Date: Feb. 25, 2009

(30) Foreign Application Priority Data
Jul. 28, 2006 (DE) 10 2006 035 750.7

(51) Int. Cl. H01L 51/30; H01L 51/40; H01B 1/12

(52) U.S. Cl. 257/40; 438/99; 252/500; 257/E51.024

(57) ABSTRACT

The invention relates to a material for producing a functional layer of an organic electronic component, in particular a material suitable for processing by printing. In the material proposed according to the invention, a functional substance is present in a polymer matrix, e.g. in dissolved or suspended fashion.

The invention relates to a material for producing a functional layer of an organic electronic component, in particular a material suitable for processing by printing.

There are known printable materials in particular for organic electronic components such as organic active components such as, for example, diodes, transistors, capacitors, self-emissive and/or photovoltaic components, components based on electrochromic layers, etc., which preferably comprise polymeric substances in a solvent. By dissolving the substance in the specific solvent or by producing a stable suspension, it is processed to form a printable solution or paste. The solvent has to be removed again after application. These work steps make a not inconsiderable contribution to increasing the overall expense of the electronic organic components.

Thus, although on the whole inexpensive organic electronic components can be produced, the materials for producing the individual conductive, semiconducting and insulating functional layers have still not been fully optimized with regard to printability or some other production method suitable for mass production. Particularly in the production of the often metallic conductive layers, it is still necessary to resort to complicated (that is to say taking place under an inert gas atmosphere for example) production methods such as vapor deposition, chemical vapor deposition and other methods that can only be performed under a protective gas atmosphere.

Therefore, it is an object of the present invention to provide a material or a matrix for different functional layers of organic electronic components which is processable in simple and therefore cost-effective work steps.

The invention relates to a material for a functional layer of an organic electronic component, wherein a conductive, semiconducting photoactive and/or thermoactive, self-emissive, electrochromic and/or insulating substance is dissolved or contained in a polymer as matrix such that the functional properties of the functional substance are at least retained in the polymer matrix or even positively reinforced by the properties of the polymeric matrix, while the polymer matrix brings about the simple processability and stability of the functional substance. The invention likewise relates to the production of a gel or a sol which is suitable for an organic electronic component and which contains, in a polymer matrix, the functional substance for forming the functional conductive, semiconducting, photoactive, self-emissive, electrochromic and/or insulating layer.

The invention for the first time enables the cost-effective processing and/or application of otherwise unstable functional materials for organic electronics.

The polymer can serve just as a matrix, that is to say be inactive in the overall system, or actively improve the functionality of the component. In this respect, the polymer is actively or inactively involved in the overall system, while it stabilizes the functional substance.

The material is present for example as a blend of different filled polymer matrices and/or as a material combination or mixture.

The functional substance is “contained” in the material, that is to say contained for example in suspended fashion or in a manner stabilized in sol/gel form, for example stabilized physically and/or chemically. In this case, it may perfectly well happen that the material contains solvent residues which are no longer detectable in the finished component, after the production of the functional layer.

The “material for the functional layer” denotes the combination of the polymeric matrix material with the functional substance contained, wherein the material always comprises at least both of these, but any desired further substances such as, for example, additives for better processability, catalysts, color pigments, conductivity pigments, etc. can be added.

An organic electronic component can be an organic field effect transistor, an organic diode, an organic capacitor, an organic photovoltaically active cell, an organic light-emitting element, an organic electrochromic layer, an organic photodetector or any other electronic component which can be produced in a manner suitable for mass production.

The term “printing medium” generally denotes what is applied by being printed. This concerns the ink during printing, by way of example. For this purpose, the printing medium has a specific viscosity and a specific rheology. The values of these parameters vary greatly according to the printing methods used and can be looked up in standard works on printing technology such as, for example, in the book by Helmut Kipphan “Handbuch der Printmedien” [“Handbook of Printing Media”] Springer Verlag. The viscosity of a printing medium accordingly ranges from pasty (approx. 100 Pa*s) to runny (approx. 1 mPa*s). A printing medium is generally a liquid, that is to say has flowability, hut it converts into a solid after printing. For this purpose, either solvent escapes and/or crosslinking takes place. A printing medium is constituted such that, during the interaction with the impression cylinder and during the interaction with the printing stock (where it is printed on), it wets the respective surfaces of the printing stock and/or of the impression cylinder. In this case, the printing medium must not bleed away, for example. Preferably, volatile solvents in the printing medium will be removable again, whereas in general no solvent escapes in the case of UV/thermally curing resists as printing medium.

In principle, no limits are imposed on the polymer which can be used as matrix material according to the invention. All types of polymeric plastics can be involved, for example all known semiconducting polymeric plastics such as polymers based on PEDOT/PSS or PANI, polythiophene, polyfluorene, PPVs or the like can be used.

In contrast to the systems used heretofore, the polymer here not only serves as an aid for processability and/or for stabilization, but can also contribute as material for reinforcing the functional properties of the functional layer. Thus, by way of example, in the production of a photovoltaically active layer, it is possible to take a polymer matrix which has a light-intensifying effect; in the case of FETs or generally all conductive layers, the polymer matrix can bring about a stabilization of the overall system.

According to another embodiment of the invention, the polymer matrix can undertake the stabilization of the overall system and/or an additional function (e.g. photovoltaically active, OFETs . . . ).

Likewise, for producing a conductive layer, for example with a metal as functional substance, it is possible to use a conductive or semiconducting polymer matrix, whereby the conductivity of the material is enhanced.

The invention provides gels or sols, that is to say stable suspensions of functional substances and/or nanoparticles of the functional substances having specific functional properties which can be printed simply and advantageously under standard conditions.

All substances for producing organic electronic components are appropriate as the functional substances or functional basic substances. In particular, in that way photochromic and/or thermochromic particles or nanoparticles, sensitive metal particles or metal alloy particles, dye particles or other charge-transfer particles can be incorporated in polymer matrices. These particles also improve the performance of organic photo detectors and/or electrochromic elements. Hitherto it had not yet been possible to incorporate these particles cost-effectively since these particles had usually been processable only in complicated deposition processes.

The functional substances employed include n-conducting dyes (electron acceptors) for example in combination with p-conducting polymeric carrier materials, such as transition metal complexes. Ruthenium complexes, iron complexes and other complexes such as AlQ3, boron complexes or the like shall be mentioned by way of example.

Further functional substances are photochromic and thermochromic pigments. Moreover, the functional substances used include nanoparticles with solubilizing side groups such as e.g. alkyl groups, (e.g. silver nanoparticles, silicon nanoparticles, gold nanoparticles, zinc oxide, gallium arsenide, indium-phosphorus compounds or the like), from which antennas, for example are printed.

Moreover, low-molecular-weight additives for functional modification or doping of the polymeric carrier material can be added as functional substances. Examples thereof include FeCl₃, I₂, PSS.

It is also possible to use for example anionic and/or acid dyes (e.g. indigo carmine, fuchsin), metal complex dyes such as organic metal complex dyes (copper complexes, chromium complexes, palladium complexes, cyano-metal complexes, generally transition metal complexes) and/or inorganic metal complex dyes (cobalt pigments, chromium complexes (chromium oxide green), Egyptian blue, iron oxide pigments, indigo, purple, cinnabar . . . ), boron complexes, aluminum complexes, Lewis acids (e.g. FeCl₃), halogens (e.g. I₂), polystyrenesulfonic acid (PSS), Lewis bases (e.g. amines), reducing agents, oxidizing agents, redox systems or allotropes.

Moreover, it is possible to use nanoparticles with solubilizing side groups such as e.g. alkyl groups (e.g. Ag-nanoparticles, Si-nanoparticles, Au-nanoparticles, zinc oxide, GaAs, InP, nanotubes, in particular carbon nanotubes, e.g. as electrode or antenna materials, both in dissolved form and in suspended form. The publication by Wessels et al. in JACS, 2004, 126, 3349-3356 shows that Au nanoparticles can be produced in soluble form and can thus be printed in a polymer matrix.

The invention surprisingly gives rise to materials which can be used to produce extremely thin functional layers for electronic organic components for example with a thickness of 10 to 500 nm (nm to μm range possible) by means of simple printing methods in cost-effective roll-to-roll printing processes and/or by spin-coating. For example, layer thicknesses of 10-300 nm are achieved during the processing of gold nanoparticles (˜4 nm) in solution in polythiophene as polymeric matrix (for the results in PFET, see the exemplary application).

N-conducting dyes (electron acceptors) can be employed in combination with p-conducting polymeric carrier materials in dye/Grätzel solar cells (e.g. Ru-complexes, Fe-complexes, possibly AlQ3, boron-complexes . . . ).

Photochromic and thermochromic pigments such as e.g. Leuco dyes, e.g. indigo white, or spironaphthoxazines and/or naphthopyrans, for example with aluminum, gold bronze, cadmium, can be printed from solution. The extent to which the solvents or solvent can still be detected in the layer after the production of the functional layer may vary and is dependent firstly on the type of solvent and secondly on the overall production process up to encapsulation.

Dissolved or suspended nanoparticles, such as, for example, nanotubes, in particular carbon nanotubes, can be used as electrode and/or antenna materials. Low-molecular-weight additives such as FeCl₃, I₂, PSS can serve for functional modification (doping) of the polymeric carrier material.

Exemplary Application for Gold Nanoparticles
Production of gold nanoparticles with solubilizing groups for use in organic solvents such as, for example, toluene (J. M. Wessels et al., Optical and Electrical Properties of Three-Dimensional Interlinked Gold Nanoparticle Assemblies; JACS 2004, 126, 3349-3356)
Mixture of the gold nanoparticles dissolved in toluene with polymeric p-type or n-type semiconductors that are dissolved (in organic solvents) is possible in different concentrations. The solutions are stable.
Use of the mixture (not a suspension but rather a genuine solution) for all customary coating methods such as spin-coating or all printing methods. Already disclosed for spin-coating and various printing methods (at PolyIC and Kurz).
Functionality of the carrier material, for example P3HT is improved:

All concentrations of metal nanoparticles (e.g. gold nanoparticles) can be set

→ The functionality of the nanoparticles compared with the polymeric semiconducting carrier material is predominant at high concentrations

→ Metals can be printed from solution, for electrodes or antennas

The advantage of the invention can be seen primarily in the fact that in contrast to the solvents of the polymeric functional materials which made the latter processable by printing according to the prior art, the polymer matrix according to the invention can be retained in the finished component and can even positively reinforce the functional properties of the material depending on the choice of the matrix. The printing of additives which would not be printable, for example in the roll-to-roll process, without a polymer matrix is therefore made possible.

1. A material for a functional layer of an organic electronic component, comprising
a polymer and
at least one functional substance in the polymer for forming the polymer into a matrix and having functional properties comprising being conductive, semiconducting, photoactive and/or thermoactive, self-emissive electrochromic and/or insulating wherein the functional properties of the functional substance are retained and/or reinforced in the polymer matrix for providing the polymer with improved processability and stability than otherwise exhibited by the polymer without the functional substance.

2. The material as claimed in claim 1 wherein the polymer matrix is arranged to be applied to a surface of a substrate as a printing medium.

3. The material as claimed in claim 1 arranged as a printing medium exhibiting conventional printing medium viscosity and rheology parameters.

4. The material as claimed in claim 1 wherein the at least one functional substance exhibits a relatively low molecular weight.

5. The material as claimed in claim 1 wherein the at least one functional substance comprises an n-conducting dye in combination with a p-conducting polymer matrix.

6. The material as claimed in claim 1 wherein the at least one functional substance comprises a photochromic and/or a thermochromic element.

7. The material as claimed in claim 1 wherein the at least one functional substance comprises nanoparticles.

8. The material as claimed in claim 1 wherein the at least one functional substance comprises nanoparticles and wherein the nanoparticles are present at least in part as nanotubes.

9. The material as claimed in claim 1 wherein the at least one functional substance comprises nanoparticles with solubilizing side chains and/or in a solvent.

10. The material as claimed in claim 1 wherein the polymer matrix further includes a relatively low-molecular-weight additional substance for the functional modification of the polymer matrix.

11. The material as claimed in claim 1 wherein the material comprises one of a gel, a sol or a suspension, the polymer matrix and the at least one functional substance for forming a functional conductive, semiconducting, photoactive and/or thermoactive self-emissive, electrochromic and/or insulating layer for an organic electronic component.

12. A method for producing the organic electronic component of claim 1 comprising forming the component with a functional layer comprising the material as claimed in claim 1.

13. A method for producing the organic electronic component of claim 11 comprising forming the component by printing the at least one functional layer on a further layer.

14. In an organic electronic component, the combination comprising:
a first layer; and
on the first layer, a functional layer for the electronic component comprising the material as claimed in claim 1.
